(19) United States
(12) Patent Application Publication
(10) Pub. No.: US 2025/0149316 A1
(43) Pub. Date: May 8, 2025

(54) PLASMA PROCESSING METHOD AND PLASMA PROCESSING APPARATUS

(71) Applicant: Tokyo Electron Limited, Tokyo (JP)

(72) Inventors: Naoki MATSUMOTO, Miyagi (JP); Toshihisa OZU, Miyagi (JP); Satoru NAKAMURA, Miyagi (JP); Yusuke SHIMIZU, Gyeonggi-do (KR)

(73) Assignee: Tokyo Electron Limited, Tokyo (JP)

(21) Appl. No.: 19/004,463

(22) Filed: Dec. 30, 2024

Related U.S. Application Data
(63) Continuation of application No. PCT/JP2023/023874, filed on Jun. 27, 2023.

(30) Foreign Application Priority Data
Jun. 30, 2022 (JP) 2022-106263

(51) Int. Cl. H01J 37/32

(52) U.S. Cl. CPC H01J 37/32926; H01J 37/32724; H01J 37/32935

(57) ABSTRACT

A technology for reducing variation in an ion flux distribution will be provided. There is provided a plasma processing method for performing plasma processing in a plasma processing apparatus including a chamber and a substrate support disposed in the chamber, the plasma processing performed on a substrate placed at the substrate support by generating plasma in the chamber. The plasma processing method includes: (a) the step of storing, in memory, first distribution data that is data relating to a distribution of an ion flux that occurs between the plasma generated in the chamber and a first substrate placed at the substrate support; (b-a) the step of placing a second substrate at the substrate support; and (b-b) a plasma processing step of generating the plasma in the chamber based on the first distribution data to perform the plasma processing on the second substrate.

### CROSS-REFERENCE TO RELATED APPLICATIONS

This application is a bypass continuation application of international application No. PCT/JP2023/023874 having an international filing date of Jun. 27, 2023 and designating the United States, the international application being based upon and claiming the benefit of priority from Japanese Patent Application No. 2022-106263, filed on Jun. 30, 2022, the entire contents of which are incorporated herein by reference.

### TECHNICAL FIELD

Exemplary embodiments of the present disclosure relate to a plasma processing method and a plasma processing apparatus.

### BACKGROUND

As a technology for measuring plasma at the surface of a wafer, there is an on-wafer monitoring system described in JP-A-2003-282546.

### CITATION LIST

### Patent Documents

PTL 1: JP-A-2003-282546

### SUMMARY

The present disclosure provides a technology for reducing variation in an ion flux distribution.

According to one or more embodiments of the present application of the present disclosure, there is provided a plasma processing method for performing plasma processing in a plasma processing apparatus including a chamber and a substrate support disposed in the chamber, the plasma processing performed on a substrate placed at the substrate support by generating plasma in the chamber, the method including: (a) the step of storing in advance first distribution data that is data relating to a distribution of an ion flux that occurs between the plasma generated in the chamber and a first substrate placed at the substrate support; (b-a) the step of placing a second substrate at the substrate support; and (b-b) a plasma processing step of generating the plasma in the chamber based on the first distribution data to perform the plasma processing on the second substrate.

According to the exemplary embodiment of the present disclosure, a technology for reducing variation in an ion flux distribution can be provided.

### BRIEF DESCRIPTION OF DRAWINGS

FIG. 1 illustrates an example of the configuration of a plasma processing system according to one or more embodiments of the present application.

FIG. 2 illustrates an example of the configuration of a capacitively-coupled plasma processing apparatus according to one or more embodiments of the present application.

FIG. 3 shows an example of the upper surface of a substrate support 11 according to one or more embodiments of the present application.

FIG. 4 shows an example of a cross section of the substrate support 11 according to one or more embodiments of the present application.

FIG. 5 is a block diagram showing an example of the configuration of a control substrate 80 according to one or more embodiments of the present application.

FIG. 6 is a flowchart showing a plasma processing method according to one exemplary embodiment according to one or more embodiments of the present application.

FIG. 7 is a flowchart showing an example of step ST1 according to one or more embodiments of the present application.

FIG. 8 is a flowchart showing an example of step ST2 according to one or more embodiments of the present application.

FIG. 9 shows an example of reference distribution data according to one or more embodiments of the present application.

FIG. 10 is a flowchart showing an example of step ST3 according to one or more embodiments of the present application.

FIG. 11 shows an example of first distribution data according to one or more embodiments of the present application.

FIG. 12 is a flowchart showing an example of step ST4 according to one or more embodiments of the present application.

FIG. 13A diagrammatically shows an example of an ion flux that occurs between plasma and the assembly of a substrate W and a ring assembly 112 according to one or more embodiments of the present application.

FIG. 13B shows an example of the distribution of the ion flux Ti according to one or more embodiments of the present application.

FIG. 14A diagrammatically shows an example of the ion flux that occurs between the plasma and the assembly of the substrate W and the ring assembly 112 according to one or more embodiments of the present application.

FIG. 14B shows an example of the distribution of the ion flux Ti according to one or more embodiments of the present application.

FIG. 15 is a flowchart showing an example of an in-plane correction step according to one or more embodiments of the present application.

FIG. 16 illustrates another example of the configuration of the capacitively-coupled plasma processing apparatus according to one or more embodiments of the present application.

### DETAILED DESCRIPTION

One or more embodiments of the present application will be described below.

According to one or more embodiments of the present application, there is provided a plasma processing method for performing plasma processing in a plasma processing apparatus including a chamber and a substrate support disposed in the chamber, the plasma processing performed on a substrate placed at the substrate support by generating plasma in the chamber. The plasma processing method includes: (a) the step of storing in advance first distribution data that is data relating to a distribution of an ion flux that occurs between the plasma generated in the chamber and a first substrate placed at the substrate support; (b-a) the step of placing a second substrate at the substrate support; and (b-b) a plasma processing step of generating the plasma in the chamber based on the first distribution data to perform the plasma processing on the second substrate.

According to one or more embodiments of the present application, the storing step (a) includes the steps of (a-a) placing the first substrate at the substrate support, (a-b) generating the plasma in the chamber to perform the plasma processing on the first substrate, (a-c) supplying power to each of multiple heaters disposed in the substrate support, (a-d) acquiring the power supplied to each of the multiple heaters in the state in which the plasma is generated in the chamber, and (a-e) calculating the first distribution data based on the power acquired for each of the multiple heaters in the first power acquisition step.

According to one or more embodiments of the present application, the plasma processing method further includes the steps of: (c-a) placing a reference substrate at the substrate support; (c-b) generating the plasma in the chamber to perform the plasma processing on the reference substrate; (c-c) supplying power to each of multiple heaters disposed in the substrate support; (c-d) acquiring the power supplied to each of the multiple heaters in the state in which the plasma is generated in the chamber; and (c-e) calculating reference distribution data that is data indicating a distribution of an ion flux that occurs between the reference substrate and the plasma, the reference distribution data being calculated based on the power acquired for each of the multiple heaters in the reference power acquisition step, and in the plasma processing step (b-b), the plasma is generated based on the reference distribution data and the first distribution data.

According to one or more embodiments of the present application, the plasma processing step (b-b) includes generating the plasma in the chamber based on a difference between the reference distribution data and the first distribution data.

According to one or more embodiments of the present application, the plasma processing apparatus further includes a storage configured to store a table that associates (1) an amount of change in a distribution of an electron density of the plasma generated in the chamber with (2) an amount of change in a distribution of the ion flux that occurs between the substrate placed at the substrate support and the plasma generated in the chamber, and the plasma processing step (b-b) includes the step of controlling the distribution of the electron density based on the difference between the reference distribution data and the first distribution data by referring to the table stored in the storage.

According to one or more embodiments of the present application, the plasma processing apparatus further includes multiple electromagnets disposed so as to face the substrate support, and the step of controlling the distribution of the electron density includes the step of controlling at least one of a current and a voltage supplied to the multiple electromagnets to control the distribution of the electron density.

According to one or more embodiments of the present application, the substrate support has a substrate supporting surface configured to support the substrate, the substrate support surface has multiple support regions, and the multiple heaters are disposed in the substrate support in the respective multiple support regions.

According to one or more embodiments of the present application, the reference substrate, the first substrate, and the second substrate each include a mask film having the same opening pattern.

According to one or more embodiments of the present application, the plasma processing apparatus further includes a storage configured to store a table that associates (1) an amount of change in a distribution of a bias voltage that occurs between the substrate placed at the substrate support and the plasma generated in the chamber with (2) an amount of change in a distribution of an ion flux that occurs between the substrate placed at the substrate support and the plasma generated in the chamber, and the plasma processing step (b-b) includes the step of controlling the distribution of the bias voltage based on a difference between the reference distribution data and the first distribution data by referring to the table stored in the storage.

According to one or more embodiments of the present application, the plasma processing apparatus further includes a ring assembly disposed around the substrate support, and the step of controlling the distribution of the bias voltage includes controlling a voltage applied to the ring assembly to control the distribution of the bias voltage.

According to one or more embodiments of the present application, the plasma processing apparatus further includes a ring assembly disposed around the substrate support, and an actuator configured to adjust a height of the ring assembly relative to a height of the substrate support, and the step of controlling the distribution of the bias voltage includes adjusting the height of the ring assembly to control the distribution of the bias voltage.

According to one or more embodiments of the present application, the plasma processing method further includes the step of generating the table, and the step of generating the table includes the steps of placing a dummy substrate at the substrate support, controlling the power supplied to each of the multiple heaters in such a way that a temperature of each of the multiple heaters becomes a predetermined temperature with the dummy substrate placed at the substrate support, placing the dummy substrate at the substrate support, generating the plasma in the chamber to perform the plasma processing on the dummy substrate, changing the distribution of the electron density of the plasma in a state in which the plasma processing is performed on the substrate including the mask film to acquire the power supplied to each of the multiple heaters, and storing (1) the amount of change in the distribution of the electron density of the plasma generated in the chamber and (2) the amount of change in the distribution of the ion flux that occurs between the substrate placed at the substrate support and the plasma generated in the chamber, in the table in association with each other.

According to one or more embodiments of the present application, a plasma processing apparatus including a chamber, a substrate support disposed in the chamber, and a controller is provided. In the plasma processing apparatus, the controller is configured to (a) store in advance first distribution data that is data relating to a distribution of an ion flux that occurs between plasma generated in the chamber and a first substrate placed at the substrate support, (b-a) place a second substrate at the substrate support, and (b-b) generate the plasma in the chamber based on the first distribution data to perform plasma processing on the second substrate.

One or more embodiments of the present application will be described below in detail with reference to the drawings. In the drawings, the same or similar elements have the same reference characters, and duplicated descriptions thereof will be omitted. Unless otherwise specified, the upward-downward positional relationship, the rightward/leftward positional relationship, and other positional relationship will be described based on the positional relationships shown in the drawings. The dimensional ratios in the drawings are not equal to actual ratios, and the actual ratios are not limited to the ratios shown in the drawings.

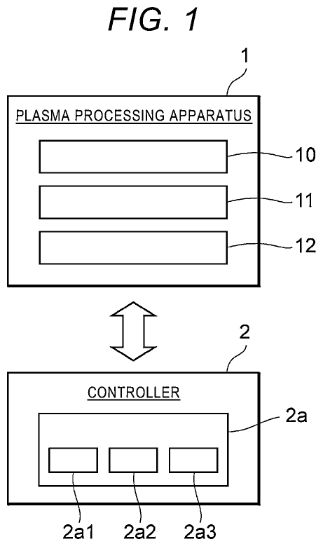

FIG. 1 illustrates an example of the configuration of a plasma processing system. According to one or more embodiments of the present application, the plasma processing system includes a plasma processing apparatus 1 and a controller 2. The plasma processing system is an example of a substrate processing system, and the plasma processing apparatus 1 is an example of a substrate processing apparatus. The plasma processing apparatus 1 includes a plasma processing chamber 10, a substrate support 11, and a plasma generator 12. The plasma processing chamber 10 has a plasma processing space. The plasma processing chamber 10 further has at least one gas supply port via which at least one processing gas is supplied into the plasma processing space, and at least one gas discharge port via which the gas is discharged from the plasma processing space. The gas supply port is connected to a gas supplier 20, which will be described later, and the gas discharge port is connected to an exhaust system 40, which will be described later. The substrate support 11 is disposed in the plasma processing space and has a substrate support surface that supports the substrate.

The plasma generator 12 is configured to generate plasma from the at least one processing gas supplied into the plasma processing space. The plasma formed in the plasma processing space may, for example, be capacitively coupled plasma (CCP), inductively coupled plasma (ICP), electron-cyclotron-resonance plasma (ECR plasma), helicon wave plasma (HWP), or surface wave plasma (SWP). Furthermore, various types of plasma generators, including an alternating current (AC) plasma generator and a direct current (DC) plasma generator, may be used. According to one or more embodiments of the present application, an AC signal (AC power) used by an AC plasma generator has a frequency within a range from 100 kHz to 10 GHz. The AC signal therefore includes a radio frequency (RF) signal and a microwave signal. According to one or more embodiments of the present application, the RF signal has a frequency within a range from 100 kHz to 150 MHz.

The controller 2 processes computer-executable instructions that instruct the plasma processing apparatus 1 to execute various steps described in the present disclosure. The controller 2 may be configured to control the elements of the plasma processing apparatus 1 to execute the various steps described herein. According to one or more embodiments of the present application, a portion or the entirety of the controller 2 may be included in the plasma processing apparatus 1. The controller 2 may include a processor 2a1, a storage 2a2, and a communication interface 2a3. The controller 2 is implemented, for example, by a computer 2a. The processor 2al may be configured to read a program from the storage 2a2 and perform various control operations by executing the read program. The program may be stored in advance in the storage 2a2, or may be acquired via a medium when necessary. The acquired program is stored in the storage 2a2, read from the storage 2a2 by the processor 2al, and executed thereby. The medium may be any of various storage media readable by the computer 2a, or may be a communication line connected to the communication interface 2a3. The processor 2al may be a central processing unit (CPU). The storage 2a2 may include a random access memory (RAM), a read only memory (ROM), a hard disk drive (HDD), a solid-state drive (SSD), or a combination thereof. The communication interface 2a3 may communicate with the plasma processing apparatus 1 via a communication line such as a local area network (LAN). The functionality of the elements disclosed herein may be implemented using circuitry or processing circuitry which includes general purpose processors, special purpose processors, integrated circuits, ASICs (“Application Specific Integrated Circuits”), FPGAs (“Field-Programmable Gate Arrays”), conventional circuitry and/or combinations thereof which are programmed, using one or more programs stored in one or more memories, or otherwise configured to perform the disclosed functionality. Processors and controllers are considered processing circuitry or circuitry as they include transistors and other circuitry therein. In the disclosure, the circuitry, units, or means are hardware that carry out or are programmed to perform the recited functionality. The hardware may be any hardware disclosed herein which is programmed or configured to carry out the recited functionality. There is a memory that stores a computer program which includes computer instructions. These computer instructions provide the logic and routines that enable the hardware (e.g., processing circuitry or circuitry) to perform the method disclosed herein. This computer program can be implemented in known formats as a computer-readable storage medium, a computer program product, a memory device, a record medium such as a CD-ROM or DVD, and/or the memory of a FPGA or ASIC.

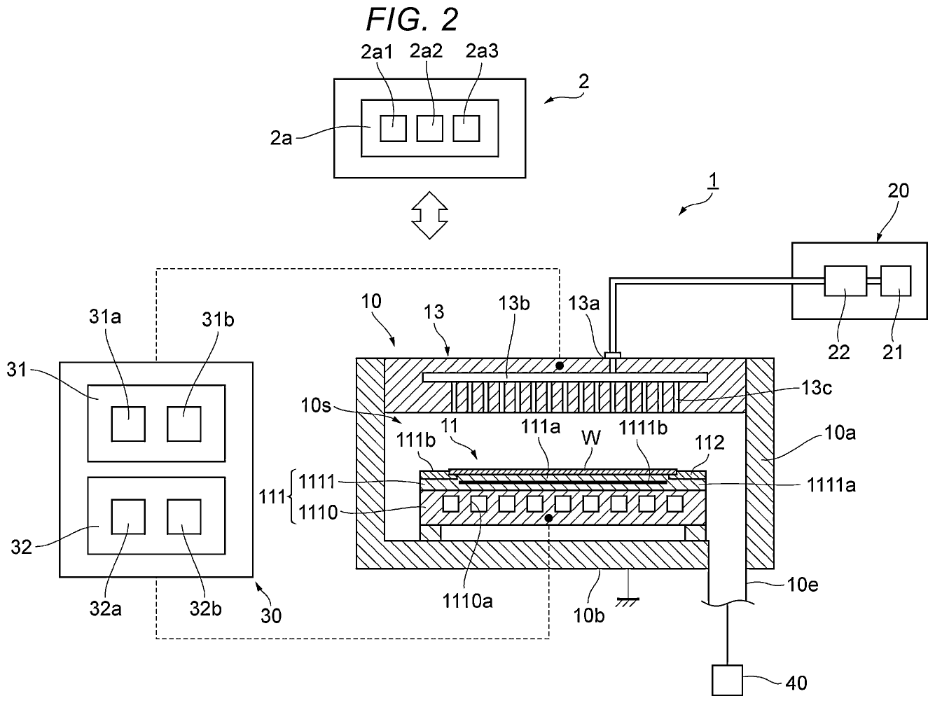

An example of the configuration of a capacitively-coupled plasma processing apparatus will be described below as an example of the plasma processing apparatus 1. FIG. 2 illustrates an example of the configuration of the capacitively-coupled plasma processing apparatus.

A capacitively-coupled plasma processing apparatus 1 includes the plasma processing chamber 10, the gas supplier 20, a power source 30, and the exhaust system 40. The plasma processing apparatus 1 further includes the substrate support 11 and a gas introduction section. The gas introduction section is configured to introduce at least one processing gas into the plasma processing chamber 10. The gas introduction section includes a shower head 13. The substrate support 11 is disposed in the plasma processing chamber 10. The shower head 13 is disposed above the substrate support 11. According to one or more embodiments of the present application, the shower head 13 constitutes at least a portion of the ceiling of the plasma processing chamber 10. The plasma processing chamber 10 has a plasma processing space 10s defined by the shower head 13, a sidewall 10a and a bottom wall 10b of the plasma processing chamber 10, and the substrate support 11. The plasma processing chamber 10 is grounded. The shower head 13 and the substrate support 11 are electrically insulated from the housing of the plasma processing chamber 10.

The substrate support 11 includes a body section 111 and a ring assembly 112. The body section 111 has a central region 111a, which supports a substrate W, and an annular region 111b, which supports the ring assembly 112. A wafer is an example of the substrate W. The annular region 111b of the body section 111 surrounds the central region 111a of the body 111 in a plan view. The substrate W is placed on the central region 111a of the body section 111, and the ring assembly 112 is disposed on the annular region 111b of the body section 111 so as to surround the substrate W on the central region 111a of the body section 111. Accordingly, the central region 111a is also called a substrate supporting surface that supports the substrate W, and the annular region 111b is also called a ring support surface that supports the ring assembly 112.

According to one or more embodiments of the present application, the body section 111 includes a base 1110 and an electrostatic chuck 1111. The base 1110 includes an electrically conductive member. The electrically conductive member of the base 1110 may function as a lower electrode. The electrostatic chuck 1111 is disposed on the base 1110. The electrostatic chuck 1111 includes a ceramic member 1111a, and an electrostatic electrode 1111b disposed in the ceramic member 1111a. The ceramic member 1111a has the central region 111a. According to one or more embodiments of the present application, the ceramic member 1111a also has the annular region 111b. Another member that surrounds the electrostatic chuck 1111, such as an annular electrostatic chuck and an annular insulating member, may have the annular region 111b. In this case, the ring assembly 112 may be disposed on the annular electrostatic chuck or the annular insulating member, or may be disposed on both the electrostatic chuck 1111 and the annular insulating member. Furthermore, at least one RF/DC electrode coupled to an RF power source 31 and/or a DC power source 32, which will be described later, may be disposed in the ceramic member 1111a. In this case, the at least one RF/DC electrode functions as the lower electrode. When a bias RF signal and/or DC signal, which will be described later, are supplied to the at least one RF/DC electrode, the RF/DC electrode is also called a bias electrode. Note that the electrically conductive member of the base 1110 and the at least one RF/DC electrode may function as multiple lower electrodes. The electrostatic electrode 1111b may instead function as a lower electrode. The substrate support 11 therefore includes at least one lower electrode.

The ring assembly 112 includes one or more annular members. According to one or more embodiments of the present application, the one or more annular members include one or more edge rings and at least one cover ring. The edge ring is made of an electrically conductive material or an insulating material, and the cover ring is made of an insulating material.

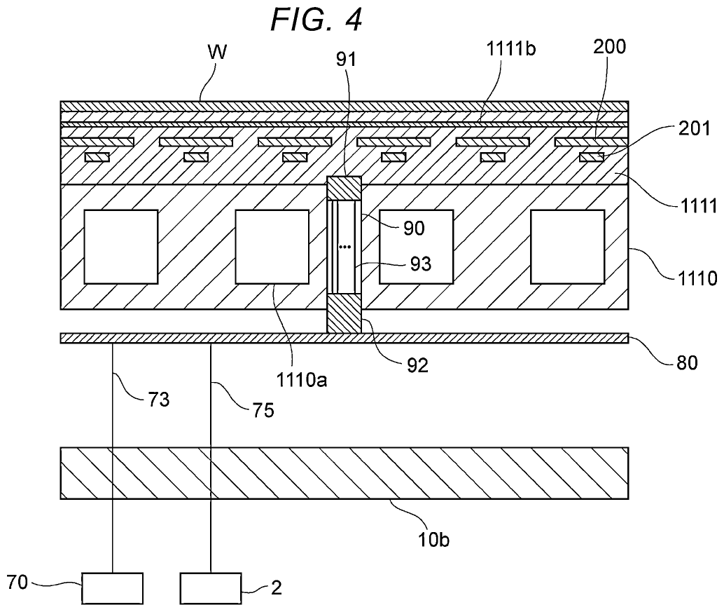

The substrate support 11 may further include a temperature controlling module configured to adjust the temperature of at least one of the electrostatic chuck 1111, the ring assembly 112, and the substrate to a target temperature. The temperature controlling module may include a heater, a heat transferring medium, a flow path 1110a, or a combination thereof. A heat transferring fluid, such as brine or gas, flows through the flow path 1110a. According to one or more embodiments of the present application, the flow path 1110a is formed in the base 1110, and one or more heaters are disposed in the ceramic member 1111a of the electrostatic chuck 1111. The substrate support 11 may further include a heat transferring gas supplier configured to supply a heat transferring gas to the gap between the rear surface of the substrate W and the central region 111a. The temperature controlling module will be described later in detail with reference to FIG. 4.

The shower head 13 is configured to introduce at least one processing gas from the gas supplier 20 into the plasma processing space 10s. The shower head 13 has at least one gas supply port 13a, at least one gas diffusion chamber 13b, and multiple gas introduction ports 13c. The processing gas supplied to the gas supply port 13a passes through the gas diffusion chamber 13b and is introduced into the plasma processing space 10s via the multiple gas introduction ports 13c. The shower head 13 further includes at least one upper electrode. The gas introduction section may include, in addition to the shower head 13, one or more side gas injectors (SGIs) attached to one or more openings formed in the sidewall 10a.

The gas supplier 20 may include at least one gas source 21 and at least one flow rate control device 22. According to one or more embodiments of the present application, the gas supplier 20 is configured to supply at least one processing gas from a corresponding gas source 21 to the shower head 13 via a corresponding flow rate control device 22. The flow rate control device 22 may include, for example, a mass flow controller or a pressure-controlled flow rate control device. The gas supplier 20 may further include at least one flow rate modulating device that modulates or pulses the flow rate of the at least one processing gas.

The power source 30 includes the RF power source 31 coupled to the plasma processing chamber 10 via at least one impedance matching circuit. The RF power source 31 is configured to supply at least one RF signal (RF power) to the at least one lower electrode and/or the at least one upper electrode. Plasma is thus formed from the at least one processing gas supplied into the plasma processing space 10s. The RF power source 31 can therefore function as at least a portion of the plasma generator 12. Furthermore, supplying the bias RF signal to the at least one lower electrode can generate a bias potential at the substrate W to attract the ionic component in the formed plasma to the substrate W.

According to one or more embodiments of the present application, the RF power source 31 includes a first RF generator 31a and a second RF generator 31b. The first RF generator 31a is coupled to the at least one lower electrode and/or the at least one upper electrode via the at least one impedance matching circuit, and configured to generate a source RF signal (source RF power) for plasma generation. According to one or more embodiments of the present application, the source RF signal has a frequency within a range from 10 MHz to 150 MHz. According to one or more embodiments of the present application, the first RF generator 31a may be configured to generate multiple source RF signals having different frequencies. The generated one or more source RF signals are supplied to the at least one lower electrode and/or the at least one upper electrode.

The second RF generator 31b is coupled to the at least one lower electrode via the at least one impedance matching circuit and configured to generate the bias RF signal (bias RF power). The frequency of the bias RF signal may be equal to or different from the frequency of the source RF signal. According to one or more embodiments of the present application, the bias RF signal has a frequency lower than the frequency of the source RF signal. According to one or more embodiments of the present application, the bias RF signal has a frequency within the range from 100 kHz to 60 MHz. According to one or more embodiments of the present application, the second RF generator 31b may be configured to generate multiple bias RF signals having different frequencies. The generated one or more bias RF signals are supplied to the at least one lower electrode. Furthermore, in various embodiments, at least one of the source RF signal and the bias RF signal may be pulsed.

The power source 30 may include the DC power source 32 coupled to the plasma processing chamber 10. The DC power source 32 includes a first DC generator 32a and a second DC generator 32b. According to one or more embodiments of the present application, the first DC generator 32a is connected to the at least one lower electrode and configured to generate a first DC signal. The generated first DC signal is applied to the at least one lower electrode. According to one or more embodiments of the present application, the second DC generator 32b is connected to the at least one upper electrode and configured to generate a second DC signal. The generated second DC signal is applied to the at least one upper electrode.

According to one or more embodiments of the present application, the first and second DC signals may be pulsed. In this case, a sequence of voltage pulses is applied to the at least one lower electrode and/or the at least one upper electrode. The voltage pulses may each have a rectangular, trapezoidal, or triangular waveform or a combination thereof. According to one or more embodiments of the present application, a waveform generator that generates the sequence of voltage pulses from a DC signal is connected to and between the first DC generator 32a and the at least one lower electrode. The first DC generator 32a and the waveform generator therefore constitute a voltage pulse generator. When the second DC generator 32b and the waveform generator constitute the voltage pulse generator, the voltage pulse generator is connected to the at least one upper electrode. The voltage pulses may each have the positive or negative polarity. The sequence of the voltage pulses may further include one or more positive-polarity voltage pulses and one or more negative-polarity voltage pulses in one cycle. The first DC generator 32a and the second DC generator 32b may be provided in addition to the RF power source 31, or the first DC generator 32a may be provided in place of the second RF generator 31b.

The exhaust system 40 may be connected, for example, to a gas discharge port 10e provided at a bottom portion of the plasma processing chamber 10. The exhaust system 40 may include a pressure adjusting valve and a vacuum pump. The pressure adjusting valve adjusts the pressure in the plasma processing space 10s. The vacuum pump may include a turbo molecular pump, a dry pump, or a combination thereof.

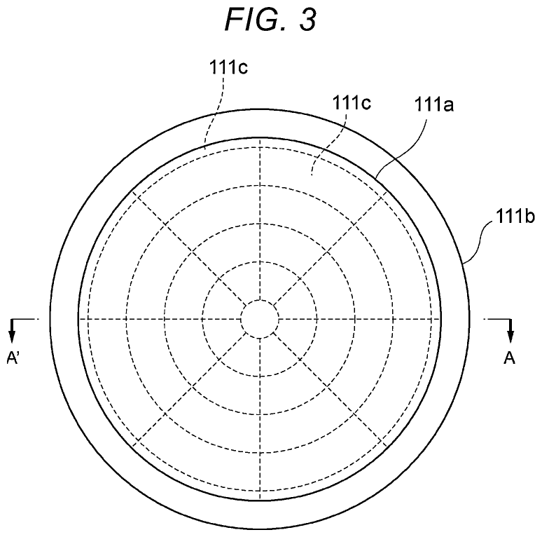

FIG. 3 shows an example of the upper surface of the substrate support 11. The substrate support 11 has the central region 111a, which supports the substrate W, and the annular region 111b, which supports the ring assembly 112, as shown in FIG. 3. The central region 111a has multiple zones 111c, as indicated by the broken lines in FIG. 3. In the present embodiment, the temperature controlling module can control the temperature of the substrate W or the substrate support 11 for each of the zones 111c. The number of the zones 111c and the area and shape of each of the zones 111c may be set as appropriate in accordance with the conditions required to control the temperature of the substrate W.

FIG. 4 shows an example of a cross section of the substrate support 11. FIG. 4 shows a portion of the cross section of the substrate support 11 taken along the line AA′ in FIG. 3. The substrate support 11 includes the electrostatic chuck 1111, the base 1110, and a control substrate 80, as shown in FIG. 4. The electrostatic chuck 1111 has multiple heaters 200 and multiple resistors 201 disposed therein. In the present embodiment, one heater 200 and one resistor 201 are disposed in the electrostatic chuck 1111 in each of the zones 111c shown in FIG. 3. In each of the zones 111c, the resistor 201 is disposed near the heater 200. In one example, the resistor 201 may be disposed between the heater 200 and the base 1110 and closer to the heater 200 than to the base 1110. The resistors 201 are each so configured that the resistance thereof changes in accordance with the temperature. In one example, the resistor 201 may be a thermistor.

The base 1110 has one or more through holes 90, which pass through the base 1110 from the upper surface thereof (surface facing electrostatic chuck 1111) to the lower surface thereof (surface facing control substrate 80). The multiple heaters 200 and the multiple resistors 201 can be electrically connected to the control substrate 80 via the through holes 90. In the present embodiment, a connector 91 is fitted into the through hole 90 at one end thereof at the upper surface of the base 1110, and a connector 92 is fitted into the through hole 90 at one end thereof at the lower surface of the base 1110. The multiple heaters 200 and the multiple resistors 201 are electrically connected to the connector 91. The multiple heaters 200 and the multiple resistors 201 may be connected to the connector 91, for example, via wires disposed in the electrostatic chuck 1111. The connector 92 is electrically connected to the control substrate 80. In addition, multiple wires 93, which electrically connect the connector 91 and the connector 92 to each other, are disposed in the through hole 90. The multiple heaters 200 and the multiple resistors 201 can thus be electrically connected to the control substrate 80 via the through holes 90. Note that the connector 92 may function as a support member that fixes the control substrate 80 to the base 1110.

The control substrate 80 is a substrate at which elements that control the multiple heaters 200 and/or the multiple resistors 201 are disposed. The control substrate 80 can be disposed so as to face the lower surface of the base 1110 in parallel to the lower surface. The control substrate 80 may be disposed so as to be surrounded by electrically conductive members. The control substrate 80 may be supported by the base 1110 via a support member other than the connector 92.

The control substrate 80 can be electrically connected to a power supplier 70 via wiring 73. That is, the power supplier 70 can be electrically connected to the multiple heaters 200 via the control substrate 80. The power supplier 70 generates power to be supplied to the multiple heaters 200. The power supplied from the power supplier 70 to the control substrate 80 can thus be supplied to the multiple heaters 200 via the connector 92, the wiring 93, and the connector 91. Note that an RF filter that reduces RF may be disposed between the power supplier 70 and the control substrate 80. The RF filter may instead be provided outside the plasma processing chamber 10.

The control substrate 80 can be communicatively connected to the controller 2 via wiring 75. The wiring 75 may be an optical fiber. In this case, the control substrate 80 communicates with the controller 2 via optical communication. The wiring 75 may instead be metal wiring.

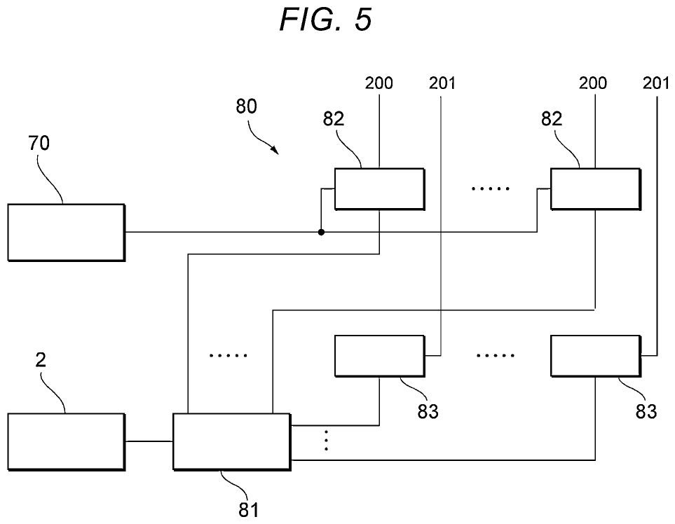

FIG. 5 is a block diagram showing an example of the configuration of the control substrate 80. A controller 81, and multiple suppliers 82 and multiple measuring sections 83, which are examples of the elements, are disposed at the control substrate 80. The multiple suppliers 82 and the multiple measuring sections 83 are provided in correspondence with the multiple heaters 200 and the multiple resistors 201, respectively. One supplier 82 and one measuring section 83 may be provided for one heater 200 and one resistor 201.

The measuring sections 83 each generate a voltage based on the resistance of the resistor 201 provided in correspondence with the measuring section 83, and supply the generated voltage to the controller 81. The measuring sections 83 may each be configured to convert the voltage generated in accordance with the resistance of the corresponding resistor 201 into a digital signal and output the digital signal to the controller 81.

The controller 81 controls the temperature of the substrate W in each of the zones 111c. The controller 81 controls the power supplied to the multiple heaters 200 based on a set temperature received from the controller 2 and the voltages indicated by the digital signals received from the measuring sections 83. As an example, the controller 81 calculates the temperatures of the resistors 201 (hereinafter also referred to as the “measured temperatures”) based on the voltages indicated by the digital signals received from the measuring sections 83. The controller 81 then controls the suppliers 82 based on the set temperature and the measured temperatures. The suppliers 82 each determine whether to supply the heater 200 with the power supplied from the power supplier 70 under the control of the controller 81. The suppliers 82 may each instead increase or decrease the power supplied from the power supplier 70 and supply the resultant power to the heater 200 under the control of the controller 81. The substrate W, the electrostatic chuck 1111, and/or the base 1110 can thus each be set at a predetermined temperature.

### <Example of Plasma Processing Method>

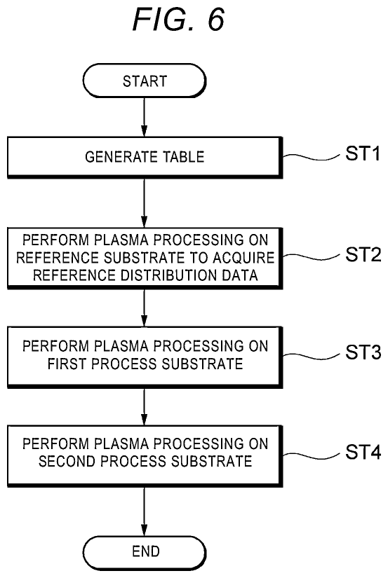

FIG. 6 is a flowchart showing a plasma processing method (hereinafter also referred to as “present processing method”) according to one exemplary embodiment. The present processing method includes the step of generating a table (ST1), the step of performing plasma processing on a reference substrate to acquire reference distribution data (ST2), the step of performing plasma processing on a first process substrate (ST3), and the step of performing plasma processing on a second process substrate (ST4), as shown in FIG. 6. The process in each of the steps may be executed by the plasma processing system shown in FIG. 1. In the following description, the controller 2 controls each section of the plasma processing apparatus 1 by way of example to perform the present processing method.

### (Step ST1: Generating Table)

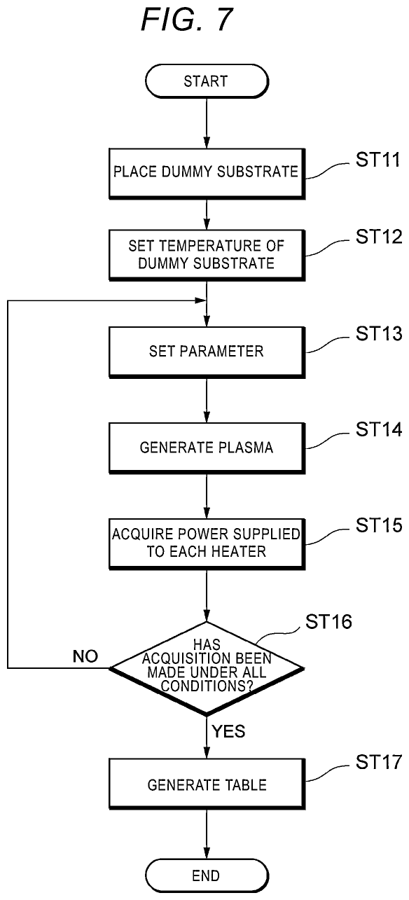

FIG. 7 is a flowchart showing an example of step ST1. The table generated in step ST1 may be a table that stores the amount of change in one or more parameters relating to the plasma generation and the amount of change in the distribution of an ion flux that occurs due to the amount of change with the two amounts associated with each other. The ion flux occurs between the substrate W placed at the substrate support 11 and the plasma generated in the plasma processing chamber 10. The ion flux may include an ion flux that occurs between the ring assembly 112 and the plasma generated in the plasma processing chamber 10.

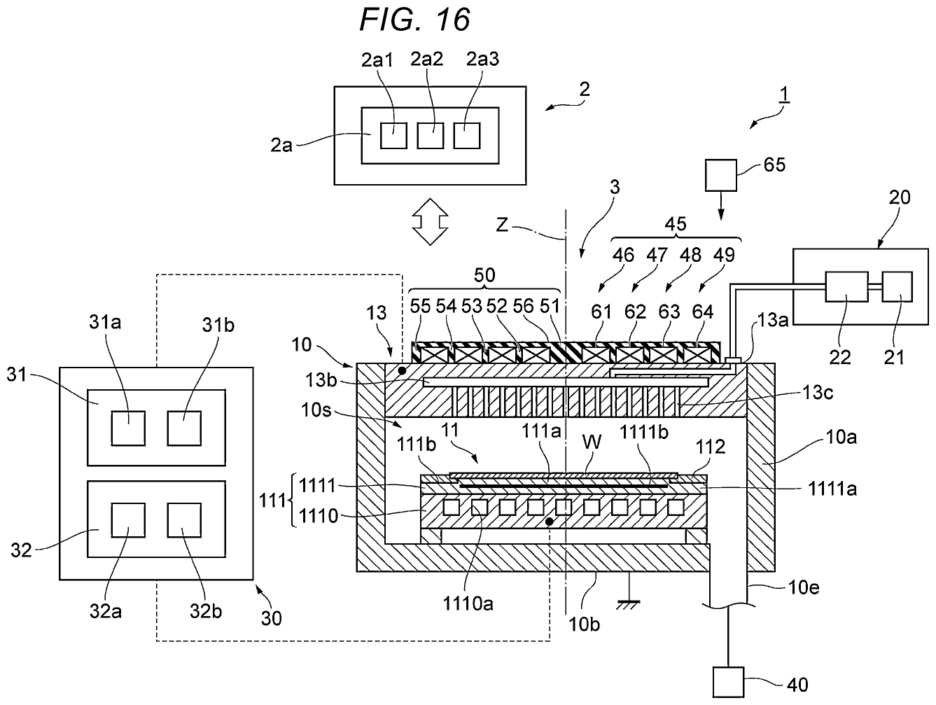

In one example, the parameter may be the magnetic flux density of a magnetic field applied to the interior of the plasma processing chamber 10 or any other parameter that can change the electron density distribution generated in the plasma processing chamber 10. As an example, the plasma processing apparatus 1 may have multiple electromagnets (see FIG. 16) configured to apply a magnetic field to the interior of the plasma processing chamber 10, in which case, the parameter may, for example, be a current and/or a voltage supplied to the multiple electromagnets.

In one example, the parameter may be a parameter that can change the distribution of a bias voltage that occurs between the substrate W placed at the substrate support 11 and the plasma generated in the plasma processing chamber 10. As one example, the electrostatic chuck 1111 may include an electrode configured to apply a voltage to the ring assembly 112, in which case, the parameter may be the voltage applied to the ring assembly 112.

The parameter may be a parameter relating to the hardware configuration of the plasma processing apparatus 1. As one example, the parameter may be the height of the ring assembly 112. The height of the ring assembly 112 may be the height of the surface of the ring assembly 112 relative to the height of the substrate supporting surface of the sub strate support 11 or the substrate W.

Step ST1 includes the step of placing a dummy substrate (ST11), the step of setting the temperature of the dummy substrate (ST12), the step of setting a plasma processing parameter (ST13), the step of generating the plasma (ST14), the step of acquiring the power supplied to each of the heaters (ST15), the step of ascertaining the acquisition of the supplied power (ST16), and the step of generating the table (ST17), as shown in FIG. 7. In one example, step ST1 may be executed at the timing when a predetermined operation of instructing the plasma processing apparatus 1 to start generating the table.

First, in step ST11, a dummy substrate is placed at the substrate support 11. In one example, the dummy substrate may be a substrate at which no film is formed. The dummy substrate may, for example, be a silicon wafer. Thereafter, in step ST12, the temperature of the dummy substrate is set. In one example, the controller 2 controls the controller 81 disposed in the control substrate 80 in such a way that the temperature of the dummy substrate becomes the set temperature in each of the zones 111c. The controller 2 acquires the power supplied to each of the heaters 200 in the state in which the temperature of the dummy substrate is stable at the set temperature, and stores the acquired power in the storage 2a. Note that the state in which the temperature of the dummy substrate is stable at the set temperature may be the state after a predetermined period has elapsed since the dummy substrate has been placed at the substrate support 11.

The controller 2 may instead acquire the power supplied to each of the heaters 200 in the state in which no dummy substrate is placed at the substrate support 11 but the temperature of the electrostatic chuck 1111 becomes stable at the set temperature, and stores the acquired power in the storage 2a.

After the temperature of the dummy substrate becomes stable at the set temperature, the parameter for the plasma processing performed on the dummy substrate is set in step ST13. The parameter may be the same as the parameter for the plasma processing performed on the reference substrate, the first process substrate, and the second process substrate in steps ST2 to ST4, which will be described later. The plasma processing may include plasma etching performed to form semiconductor devices at the reference substrate, the first process substrate, and the second process substrate.

The plasma processing parameter may include the type of the processing gas, the flow rate of the processing gas, the frequency, power, and duty ratio of the source RF signal, the frequency, power/voltage, and duty ratio of a bias signal, the pressure in the plasma processing chamber 10, the voltage applied to the ring assembly 112, the height of the ring assembly 112, and the distribution of the magnetic field applied to the interior of the plasma processing chamber 10. Thereafter, in step ST14, the plasma is generated, and the plasma processing is performed on the dummy substrate.

Thereafter, in step ST15, the power supplied to each of the multiple heaters 200 is acquired. In steps ST14 and ST15, the controller 2 can control the power supplied to each of the heaters 200 in such a way that the temperature of the dummy substrate in each of the zones 111c becomes the set temperature. The controller 2 then acquires the power supplied to each of the multiple heaters 200 in the state in which the plasma has been generated in the plasma processing chamber 10. The controller 2 can store the power supplied to each of the multiple heaters 200 acquired in step ST15 in the storage 2a in association with one or more of the plasma processing parameters. In the present embodiment, the parameters may be parameters that can change the electron density distribution generated in the plasma processing chamber 10.

Thereafter, in step ST16, the controller 2 determines whether the power supplied to each of the multiple heaters 200 has been acquired under all conditions in which the parameters are changed. When the controller 2 determines that the supplied power has not been acquired under all the conditions (No in step ST16), the controller 2 returns to step ST13, and generates the plasma by changing one or more of the parameters (step ST14). The parameter may be a parameter that can change the electron density distribution generated in the plasma processing chamber 10. In one example, the parameter may be the magnetic flux density of the magnetic field applied to the interior of the plasma processing chamber 10. The parameter may instead be the voltage applied to the ring assembly 112 or the height of the ring assembly 112. Thereafter, in a state in which the plasma has been generated based on the parameter newly set in step ST13, the power to be supplied to each of the multiple heaters 200 is newly acquired (step ST15). The controller 2 can store the power supplied to each of the multiple heaters 200 acquired in step ST15 in the storage 2a in association with one or more of the parameters.

Then, when the controller 2 determines that the power supplied to each of the multiple heaters 200 has been acquired under all the conditions in which the parameters are changed (Yes in step ST16), the controller 2 stops the plasma processing. Thereafter, in step ST17, the controller 2 generates a table based on the values of the parameters and the power supplied to each of the multiple heaters 200 stored in the storage 2a. The table may be a table that associates the amount of change in each of the parameters in the plasma processing performed in step ST14 with the amount of change in the distribution of the ion flux having occurred due to the amount of change. Note that the ion flux distribution may be calculated based on a heat flux that occurs between the dummy substrate placed at the substrate support 11 and the plasma generated in the plasma processing chamber 10. For example, when the temperature of the dummy substrate placed at the substrate support 11 is constant, an ion flux Γᵢ (m⁻²s⁻¹) that occurs between the dummy substrate and the plasma generated in the plasma processing chamber 10 can be related to a heat flux Γₕₑₐₜ (W/m²) that occurs between the dummy substrate and the plasma generated in the plasma processing chamber 10 as follows:

$${Γ}_{i} \times Vdc ∝ {Γ}_{h e a t} \qquad ( 1 )$$

In Expression (1), Vdc (V) represents the bias voltage (V) that occurs between the dummy substrate and the plasma. The heat flux Γₕₑₐₜ, which occurs between the dummy substrate placed at the substrate support 11 and the plasma generated in the plasma processing chamber 10, may be calculated based on the supplied power acquired in step ST15. In one example, the heat flux Γₕₑₐₜ in each of the zones 111c may be calculated based on the expression below.

$${Γ}_{h e a t} = ( {P}_{0} - {P}_{h t r} ) / A \qquad ( 2 )$$

In Expression (2), P₀ represents the power (W) supplied to the heater 200 in the zone 111c in a state in which no plasma has been generated. That is, P₀ is the power acquired in the process ST12 and supplied to the heater 200 in the zone 111c. In Expression (2), Pₕₜᵣ represents the power (W) supplied to the heater 200 in the zone 111c in the state in which the plasma has been generated. That is, Pₕₜᵣ is the power acquired in the process ST15 and supplied to the heater 200 in the zone 111c. As an example, Pₕₜᵣ may be the power (W) supplied to the heater 200 in the zone 111c when the power (W) becomes substantially constant after the plasma is generated. In Expression (2), A represents the area (m²) of the zone 111c.

In the table generated in step ST17, the parameter stored in association with the amount of change in the ion flux may be the amount of change in the magnetic flux density of the magnetic field applied to the interior of the plasma, or the amount of change in the current and/or voltage supplied to the electromagnets that generate the magnetic field. When the temperature of the dummy substrate is constant, the ion flux Ti, which occurs between the dummy substrate and the plasma, can be related to the electron density in the plasma as follows:

$${Γ}_{i} ∝ {n}_{e} \times {( Vdc )}^{1 / 2} \qquad ( 3 )$$

In Expression (3), nₑ represents the electron density (m⁻³) in the plasma. In Expression (3), Vdc represents the bias voltage (V) that occurs between the dummy substrate and the plasma. The electron density in the plasma can be related to the magnetic flux density of the magnetic field applied to the interior of the plasma based on the expression below.

nₑ∝H (4)

In Expression (4), H represents the magnetic flux density (G). The magnetic flux density distribution of the magnetic field applied to the interior of the plasma can thus be changed to change the distribution of the ion flux that occurs between the plasma and the dummy substrate. As described above, in step ST17, the controller 2 can generate, as an example, a table in which the amount of change in the magnetic flux density distribution of the magnetic field applied to the interior of the plasma is associated with the amount of change in the distribution of the ion flux.

In the table generated in step ST17, the parameter stored in association with the amount of change in the ion flux may be a parameter that can change the distribution of the bias voltage that occurs between the substrate W placed at the substrate support 11 and the plasma generated in the plasma processing chamber 10. When the temperature of the dummy substrate is constant, the ion flux Ti, which occurs between the dummy substrate and the plasma, can be related to the bias voltage (V) that occurs between the dummy substrate and/or the ring assembly 112 and the plasma in the form of Expression (3) described above. The distribution of the bias voltage Vdc can therefore be changed to change the distribution of the ion flux that occurs between the plasma and the dummy substrate. As described above, in step ST17, the controller 2 may generate, as an example, a table in which the amount of change in the distribution of the bias voltage is associated with the amount of change in the distribution of the ion flux. The controller 2 may further generate in step ST17, as an example, a table in which the amount of change in the voltage applied to the ring assembly 112 is associated with the amount of change in the distribution of the ion flux. The controller 2 may still further generate in step ST17, as an example, a table in which the amount of change in the height of the ring assembly 112 is associated with the amount of change in the distribution of the ion flux.

### (Step ST2: Plasma Processing of Reference Substrate)

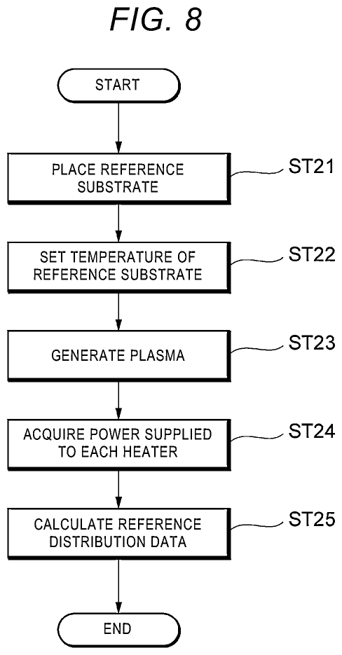

FIG. 8 is a flowchart showing an example of step ST2. In step ST2, the plasma processing is performed on the reference substrate to acquire reference distribution data. The reference substrate may be a substrate at which semiconductor devices are formed. The plasma processing may include plasma etching performed to form the semiconductor devices at the reference substrate. That is, the reference substrate may include a predetermined film, and a mask film disposed on the predetermined film. The mask film may have a predetermined opening pattern. The reference substrate may be identical to the first process substrate and/or the second process substrate, which will be described later. That is, the reference substrate may include the same film and a mask film having the same opening pattern as the first process substrate and/or the second process substrate. In step ST2, the plasma processing may be performed on the dummy substrate in place of the reference substrate to calculate the reference distribution data.

Step ST2 includes the step of placing the reference substrate (step ST21), the step of setting the temperature of the reference substrate (step ST22), the step of generating the plasma (step ST23), the step of acquiring the power supplied to each of the heaters (step ST24), and the step of calculating the reference distribution data (step ST25), as shown in FIG. 8. In one example, step ST2 may be executed after installation or maintenance of the plasma processing apparatus 1. That is, step ST2 can be executed when the plasma processing apparatus 1 is in a satisfactory state.

First, in step ST21, the reference substrate is placed at the substrate support 11. Thereafter, in step ST22, the temperature of the reference substrate is set. In one example, the controller 2 controls the controller 81 disposed at the control substrate 80 in such a way that the temperature of the reference substrate becomes the set temperature in each of the zones 111c. The controller 2 acquires the power supplied to each of the heaters 200 in the state in which the temperature of the reference substrate is stable at the set temperature, and stores the acquired power in the storage 2a. Note that the state in which the temperature of the reference substrate is stable at the set temperature may be the state after a predetermined period has elapsed since the reference substrate has been placed at the substrate support 11. The controller 2 may instead acquire the power supplied to each of the heaters 200 in the state in which no reference substrate is placed at the substrate support 11 but the temperature of the electrostatic chuck 1111 becomes stable at the set temperature, and stores the acquired power in the storage 2a.

After the temperature of the reference substrate becomes stable at the set temperature, the plasma is generated in the plasma processing chamber 10 to perform the plasma processing on the reference substrate in step ST23. The parameters used to perform the plasma processing on the reference substrate in step ST23 may be the same as the parameters set in step ST13.

Thereafter, in step ST24, the power supplied to each of the multiple heaters 200 is acquired. In steps ST23 and ST24, the controller 2 controls the power supplied to each of the heaters 200 in such a way that the temperature of the reference substrate becomes the set temperature in each of the zones 111c. The controller 2 then acquires the power supplied to each of the multiple heaters 200 in the state in which the plasma has been generated in step ST24. The controller 2 can store the power supplied to each of the multiple heaters 200 acquired in step ST24 in the storage 2a in association with one or more of the parameters.

Thereafter, in step ST25, the reference distribution data is calculated. The reference distribution data may be data on the distribution of the ion flux that occurs between the plasma generated in the plasma processing chamber 10 and the reference substrate. The ion flux distribution data may be calculated based on Expressions (1) and (2) described in step ST17.

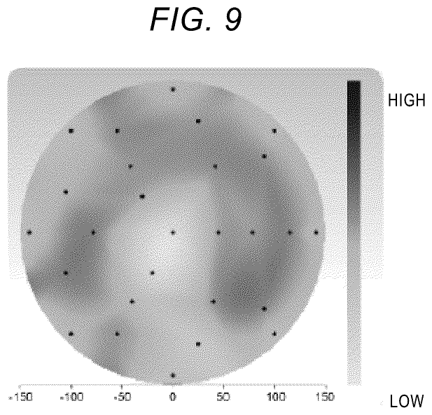

FIG. 9 shows an example of the reference distribution data. The reference distribution data can be acquired in a state in which the plasma processing apparatus 1 is in a normal state, for example, after installation or maintenance of the plasma processing apparatus 1. The reference distribution data may therefore be used as distribution data that serves as a reference for the ion flux that occurs between the plasma and the substrate. Note that multiple sets of reference distribution data may be acquired from multiple reference substrates, and one set of distribution data such as that as shown in FIG. 9 may be calculated based on the multiple sets of reference distribution data. Note that FIG. 9 shows, as an example, distribution data calculated for a substrate having a diameter of 300 mm.

### (Step ST3: Plasma Processing of First Process Substrate)

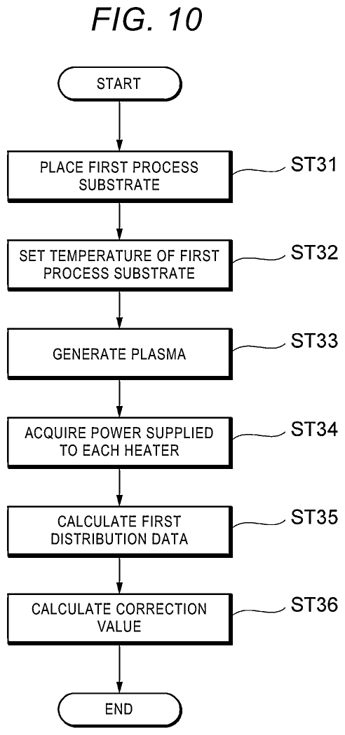

FIG. 10 is a flowchart showing an example of step ST3. In step ST3, the plasma processing is performed on the first process substrate. The first process substrate may be a substrate at which semiconductor devices are formed. The plasma processing may include plasma etching performed to form the semiconductor devices at the first process substrate. The first process substrate may have the same structure as the reference substrate. That is, the first process substrate may include the same film and a mask film having the same opening pattern as the reference substrate. The parameters used to perform the plasma processing on the first process substrate may be the same parameters used to perform the plasma processing on the reference substrate. Note that the first process substrate is an example of a first substrate. In step ST3, the plasma processing is performed on the dummy substrate in place of the first process substrate to calculate first distribution data.

Step ST3 includes the step of placing the first process substrate (step ST31), the step of setting the temperature of the first process substrate (step ST32), the step of generating the plasma (step ST33), the step of acquiring the power supplied to each of the heaters (step ST34), the step of calculating the first distribution data (step ST35), and the step of calculating a correction value (step ST36), as shown in FIG. 10. In one example, the step ST3 may be executed, after a predetermined period of time has elapsed since the process ST2 has been executed, to correct a temporal change in the plasma processing apparatus 1.

First, in step ST31, the first process substrate is placed at the substrate support 11. Thereafter, in step ST32, the temperature of the first process substrate is set. In one example, the controller 2 controls the controller 81 disposed at the control substrate 80 in such a way that the temperature of the first process substrate becomes the set temperature in each of the zones 111c. The controller 2 acquires the power supplied to each of the heaters 200 in the state in which the temperature of the first process substrate is stable at the set temperature, and stores the acquired power in the storage 2a. Note that the state in which the temperature of the first process substrate is stable at the set temperature may be the state after a predetermined period has elapsed since the first process substrate has been placed at the substrate support 11. The controller 2 may instead acquire the power supplied to each of the heaters 200 in the state in which no first process substrate is placed at the substrate support 11 but the temperature of the electrostatic chuck 1111 becomes stable at the set temperature, and stores the acquired power in the storage 2a.

After the temperature of the first process substrate becomes stable at the set temperature, the plasma is generated in the plasma processing chamber 10 to perform the plasma processing on the first process substrate in step ST33. The parameters used to perform the plasma processing on the first process substrate in step ST33 may be set under the same conditions as the parameters set in steps ST13 and ST23.

Thereafter, in step ST34, the power supplied to each of the multiple heaters 200 is acquired. In steps ST33 and ST34, the controller 2 controls the power supplied to each of the heaters 200 in such a way that the temperature of the first process substrate becomes the set temperature in each of the zones 111c. The controller 2 then acquires the power supplied to each of the multiple heaters 200 in the state in which the plasma has been generated in step ST34. The controller 2 can store the power supplied to each of the multiple heaters 200 acquired in step ST34 in the storage 2a in association with one or more of the parameters.

Thereafter, in step ST35, the first distribution data is calculated. The first distribution data may be data on the distribution of the ion flux that occurs between the plasma generated in the plasma processing chamber 10 and the first process substrate. The ion flux distribution data may be calculated based on Expressions (1) and (2) described in step ST17.

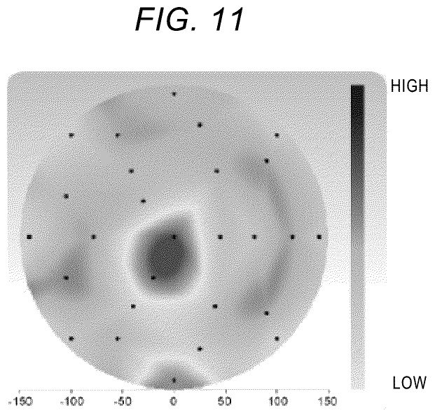

FIG. 11 shows an example of the first distribution data. The first distribution data shown in FIG. 11 is data acquired, as an example, after installation, maintenance, or any other operation is performed on the plasma processing apparatus 1 and then a predetermined period of time elapses. The first distribution data can therefore be data acquired under the same plasma processing parameters as the reference distribution data, but reflects temporal changes in consumables and other parts provided in the plasma processing apparatus 1. In the example shown in FIG. 11, the ion flux is more intense in central and lower regions than in the other regions. In view of the fact described above, a correction value is so calculated in step ST36 based on the reference distribution data and the first distribution data that the distribution of ion flux can be corrected at the second process substrate on which plasma processing is performed after the first process substrate. The correction value may be the difference between the reference distribution data and the first distribution data. Note that FIG. 11 shows, as an example, distribution data calculated for a substrate having the diameter of 300 mm.

### (Step ST4: Plasma Processing of Second Process Substrate)

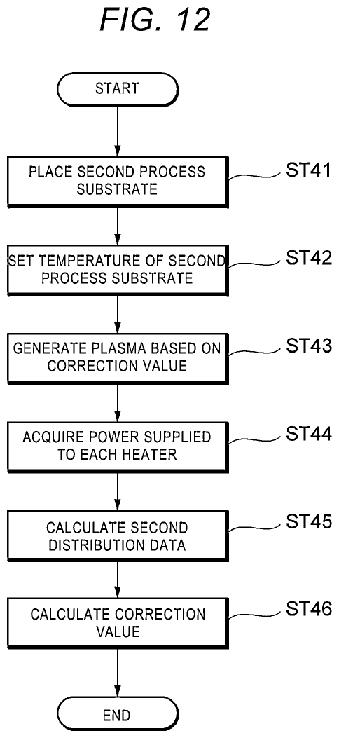

FIG. 12 is a flowchart showing an example of step ST4. In step ST4, the plasma processing is performed on the second process substrate. In step ST4, the plasma processing can be performed on the second process substrate by using the correction value acquired for the first process substrate in step ST36. In one example, the first process substrate may be a substrate to be processed first in a particular lot. The second process substrate may be a substrate to be processed after the first process substrate in the particular lot.

The second process substrate may be a substrate at which semiconductor devices are formed. The plasma processing may include plasma etching performed to form the semiconductor devices at the second process substrate. The second process substrate may have the same structure as the reference substrate and/or the first process substrate. That is, the second process substrate may include the same film and a mask film having the same opening pattern as the reference substrate and/or the first process substrate. The parameters used to perform the plasma processing on the second process substrate may be the same parameters used to perform the plasma processing on the reference substrate and/or the first process substrate. Note that the second process substrate is an example of a second substrate. In step ST4, the plasma processing is performed on the dummy substrate in place of the second process substrate to calculate second distribution data.

Step ST4 includes the step of placing the second process substrate (step ST41), the step of setting the temperature of the second process substrate (step ST42), the step of generating the plasma based on the correction value (step ST43), the step of acquiring the power supplied to each of the heaters (step ST44), the step of calculating the second distribution data (step ST45), and the step of calculating the correction value (step ST46), as shown in FIG. 12.

First, in step ST41, the second process substrate is placed at the substrate support 11. Thereafter, in step ST42, the temperature of the second process substrate is set. In one example, the controller 2 controls the controller 81 disposed at the control substrate 80 in such a way that the temperature of the second process substrate becomes the set temperature in each of the zones 111c. The controller 2 acquires the power supplied to each of the heaters 200 in the state in which the temperature of the second process substrate is stable at the set temperature, and stores the acquired power in the storage 2a. Note that the state in which the temperature of the second process substrate is stable at the set temperature may be the state after a predetermined period has elapsed since the second process substrate has been placed at the substrate support 11. The controller 2 may instead acquire the power supplied to each of the heaters 200 in the state in which no second process substrate is placed at the substrate support 11 but the temperature of the electrostatic chuck 1111 becomes stable at the set temperature, and stores the acquired power in the storage 2a.

After the temperature of the second process substrate becomes stable at the set temperature, the plasma is generated in the plasma processing chamber 10 to perform the plasma processing on the second process substrate in step ST43. Some of the parameters used to perform the plasma processing on the second process substrate in step ST43 may be set based on the correction value calculated based on the reference distribution data in step ST35. That is, in step ST43, the plasma can be generated in the plasma processing chamber 10 based on the correction value calculated based on the reference distribution data in step ST35. As an example, when the correction value is the difference between the reference distribution data and the first distribution data (difference in ion flux distribution), the controller 2 refers to the amount of change in the ion flux distribution corresponding to the correction value in the table stored in the storage 2a in step ST1. The controller 2 then sets parameters used to correct the ion flux distribution based on the amount of change in the parameter contained in the table and corresponding to the amount of change in the ion flux distribution.

In one example, the parameter may be the magnetic flux density of the magnetic field applied to the interior of the plasma, or the current and/or voltage supplied to the electromagnets that generate the magnetic field. The parameter may instead be the voltage applied to the ring assembly.

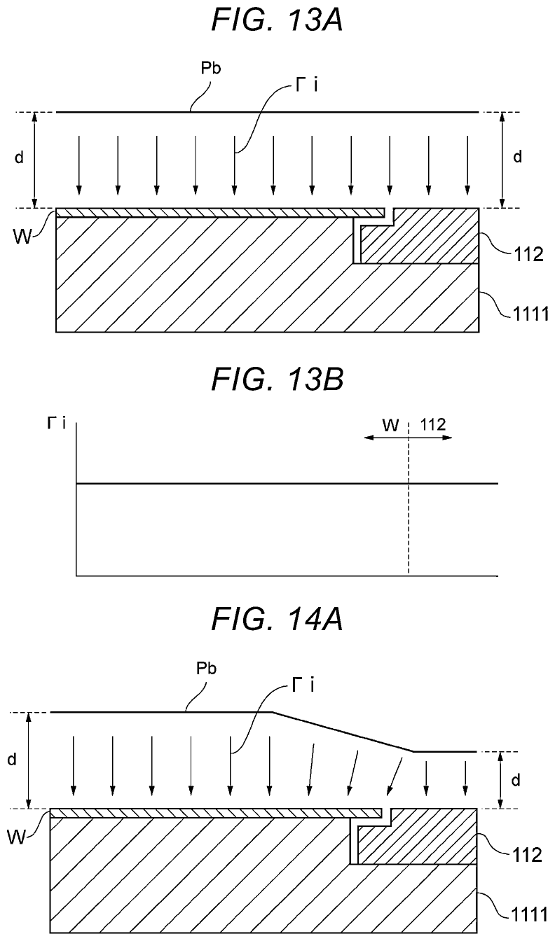

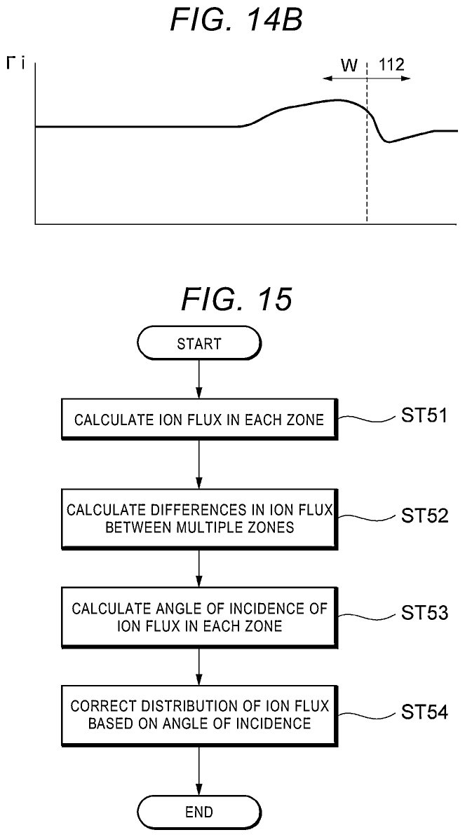

Note that generating the plasma in the plasma processing chamber 10 based on the reference distribution data may include generating the plasma after adjusting the hardware configuration based on the correction values calculated in step ST36 and/or step ST46. As an example, adjusting the hardware configuration may be adjusting the height of the ring assembly 112. The height of the ring assembly 112 may be the height of the surface of the ring assembly 112 relative to the height of the substrate supporting surface of the substrate support 11. The adjustment of the hardware configuration may be performed before step ST43. That is, the adjustment of the hardware configuration may be performed before step ST43, and then the plasma may be generated in step ST43. The generation of the plasma may also be included in the generation of the plasma in the plasma processing chamber 10 based on the reference distribution data. An example of adjusting the parameter relating to the ring assembly 112 to correct the ion flux distribution will be described with reference to FIGS. 13 and 14.

FIG. 13A diagrammatically shows the ion flux that occurs between the assembly of the substrate W and the ring assembly 112, and the plasma in the plasma processing apparatus 1 in a satisfactory state (for example, when reference distribution data is acquired in step ST2). FIG. 13B shows an example of the distribution of the ion flux Ti that occurs in the plasma processing apparatus 1 in a satisfactory state (for example, when reference distribution data is acquired in step ST2). FIG. 14A diagrammatically shows the ion flux that occurs between the assembly of the substrate W and the ring assembly 112, and the plasma in the plasma processing apparatus 1 having been used for a certain period (for example, when first distribution data is acquired in step ST3). FIG. 14B shows an example of the distribution of the ion flux Ti that occurs in the plasma processing apparatus 1 having been used for the certain period (for example, when first distribution data is acquired in step ST3). In FIGS. 13A and 14A, Pb represents the lower end of the plasma (upper end of plasma sheath). In FIGS. 13A and 14A, d represents the thickness of the plasma sheath.

In the plasma processing apparatus 1 in a satisfactory state, the thickness d of the plasma sheath may be substantially constant across the region from the substrate W to the ring assembly 112 (that is, in lateral direction in FIG. 13A), as shown in FIG. 13A. The distribution of the ion flux Ti may also be substantially constant across the region from the substrate W to the ring assembly 112, as shown in FIG. 13B. The angle of incidence of the ion flux l′i with respect to the substrate W and the ring assembly 112 may also be substantially perpendicular to the substrate W and the ring assembly 112.

On the other hand, after the plasma processing apparatus 1 has been used for a certain period of time in the satisfactory state, wear or other deterioration of the ring assembly 112 may change the thickness d of the plasma sheath above the ring assembly 112 to a thickness different from the thickness d of the plasma sheath above the substrate W, as shown in FIG. 14A. The angle of incidence of the ion flux Ti with respect to the substrate W and/or the ring assembly 112 changes accordingly near the boundary between the substrate W and the ring assembly 112, so that the shape of the plasma sheath may change. As described above, when the difference between the reference distribution data and the first distribution data (difference in ion flux distribution) occurs along the outer circumference of the substrate W, the controller 2 may adjust the parameter relating to the ring assembly 112 and generate the plasma in step ST43. As an example, the plasma processing apparatus 1 may be configured to apply a voltage to the ring assembly 112, and the controller 2 may adjust the voltage applied to the ring assembly 112 to correct the distribution of the ion flux Ti. In addition, the plasma processing apparatus 1 may include an actuator configured to adjust the height of the ring assembly 112, and the controller 2 may control the actuator to adjust the height of the ring assembly 112 to correct the distribution of the ion flux Ti. Note that the adjustment of the parameter relating to the ring assembly 112 may be performed before step ST43.

Thereafter, in step ST44, the power supplied to each of the multiple heaters 200 is acquired. In steps ST43 and ST44, the controller 2 controls the power supplied to each of the heaters 200 in such a way that the temperature of the second process substrate becomes the set temperature in each of the zones 111c. The controller 2 then acquires the power supplied to each of the multiple heaters 200 in the state in which the plasma has been generated. The controller 2 can store the power supplied to each of the multiple heaters 200 acquired in step ST44 in the storage 2a in association with one or more of the parameters.

Thereafter, in step ST45, the second distribution data is calculated. The second distribution data may be data on the distribution of the ion flux that occurs between the plasma generated in the plasma processing chamber 10 and the second process substrate. The ion flux distribution data may be calculated based on Expressions (1) and (2) described in step ST17.

Thereafter, in step ST46, the correction value is calculated based on the reference distribution data and the second distribution data. The correction value may be the difference between the reference distribution data and the second distribution data. The correction value may be used as a correction value that corrects the ion flux distribution in the plasma processing performed after the second process substrate in the lot containing the first and second process substrates.

In steps ST36 and ST46, the correction value is calculated based on the reference distribution data, but the method for calculating the correction value is not limited to the method described above. In one example, data acquired in the plasma processing in steps ST3 and ST4 may be accumulated, and the parameter in the plasma processing may be corrected based on the accumulated data to correct the ion flux distribution. The data to be accumulated may include the plasma processing parameter, the power supplied to each of the heaters, the temperature of each of the heaters, the heat flux distribution, the ion flux distribution, and the types and configurations of the substrates.

The present processing method may include, in addition to or in place of the steps described in steps ST1 to ST4, an in-plane correction step of correcting the in-plane ion flux distribution. FIG. 15 is a flowchart showing an example of the in-plane correction step. The in-plane correction step includes the step of calculating the ion flux in each of the zones 111c (ST51), the step of calculating a difference in the ion flux between adjacent ones of the multiple zones 111c (ST52), the step of calculating the angle of incidence of the ion flux in each of the zones 111c (ST53), and the step of correcting the ion flux distribution based on the calculated angle of incidence (ST54).

First, in step ST51, the ion flux in each of the zones 111c is calculated. The ion flux may be calculated by the method described in steps ST1 to ST4. Thereafter, in step ST52, a difference in the ion flux between adjacent ones of the multiple zones is calculated, and then in step ST53, the angle of incidence of the ion flux in each of the zones 111c is calculated. In step ST53, the angle of incidence of the ion flux can be calculated based on the differences in the ion flux between the multiple zones 111c calculated in step ST52 and the distances between the multiple zones 111c. The distances between the multiple zones 111c may be the distances between the resistors 201 disposed in the multiple zones 111c. Thereafter, in step ST54, the distribution of the ion flux between the multiple zones 111c is corrected based on the calculated distribution of the angles of incidence of the ion flux. In step ST54, the distribution of the ion flux between the multiple zones 111c may be corrected based on the distribution of the angles of incidence of the ion flux calculated in step ST53, as in the method described in steps ST1 to ST4. Furthermore, in step ST54, the ion flux in each of the zones 111c may be so corrected that the distribution of the ion flux in the plane of the substrate W and/or the ring assembly 112 approaches a uniform distribution.

FIG. 16 illustrates another example of the configuration of the plasma processing apparatus. According to one or more embodiments of the present application, the plasma processing apparatus 1 may include an electromagnet assembly 3 including one or more electromagnets 45. The electromagnet assembly 3 is configured to generate a magnetic field in the chamber 10. According to one or more embodiments of the present application, the plasma processing apparatus 1 includes an electromagnet assembly 3 including multiple electromagnets 45. In the embodiment shown in FIG. 16, the multiple electromagnets 45 include electromagnets 46 to 49. The multiple electromagnets 45 are provided on or above the chamber 10. That is, the electromagnet assembly 3 is disposed on or above the chamber 10. In the example shown in FIG. 16, the multiple electromagnets 45 are provided on the shower head 13.

Each of the one or more electromagnets 45 each include a coil. In the example shown in FIG. 16, the electromagnets 46 to 49 include coils 61 to 64. The coils 61 to 64 are wound around a center axis Z. The center axis Z may be an axis passing through the center of the substrate W or the substrate support 11. That is, in the electromagnet assembly 3, the coils 61 to 61 may each be a toroidal coil. The coils 61 to 64 are provided coaxially around the center axis Z at the same height position.

The electromagnet assembly 3 further includes a bobbin 50 (or yoke). The coils 61 to 64 are wound around the bobbin 50 (or yoke). The bobbin 50 is made, for example, of a magnetic material. The bobbin 50 has a columnar section 51, multiple cylindrical sections 52 to 55, and a base section 56. The base section 56 has a substantially disk-like shape, and the center axis thereof coincides with the center axis Z. The columnar section 51 and the multiple cylindrical sections 52 to 55 extend downward from the lower surface of the base section 56. The columnar section 51 has a substantially circular columnar shape, and the center axis thereof substantially coincides with the center axis Z. The radius of the columnar section 51 is, for example, 30 mm. The cylindrical sections 52 to 55 extend around the center axis Z outside the columnar section 51.

The coil 61 is wound along the outer circumferential surface of the columnar section 51 and housed in a groove between the columnar section 51 and the cylindrical section 52. The coil 62 is wound along the outer circumferential surface of the cylindrical section 52 and housed in a groove between the cylindrical section 52 and the cylindrical section 53. The coil 63 is wound along the outer circumferential surface of the cylindrical section 53 and housed in a groove between the cylindrical section 53 and the cylindrical section 54. The coil 64 is wound along the outer circumferential surface of the cylindrical section 54 and housed in a groove between the cylindrical section 54 and the cylindrical section 55.

A current source 65 is connected to each of the coils contained in the one or more electromagnets 45. The controller 2 controls the current source 65 to start and stop supplying the current to each of the coils contained in the one or more electromagnets 45, and further controls the direction of the current, and the value of the current. Note that when the plasma processing apparatus 1 includes the multiple electromagnets 45, the coils of the multiple electromagnets 45 may be connected to a single current source, or may be separately connected to different current sources.

The one or more electromagnets 45 generate a magnetic field axially symmetric with respect to the center axis Z in the chamber 10. Controlling the current supplied to each of the one or more electromagnets 45 allows adjustment of the magnetic field intensity distribution (or magnetic flux density) in the radial direction from the center axis Z. The plasma processing apparatus 1 can thus adjust the radial distribution of the density of the plasma generated in the chamber 10. Other configurations, operations, and/or functions of the plasma processing apparatus 1 shown in FIG. 16 may be the same as those of the plasma processing apparatus 1 described in the example shown in FIG. 2.

According to the exemplary embodiment of the present disclosure, variation in the ion flux distribution can be reduced. Highly uniform plasma can thus be generated in the plasma processing. In plasma etching, for example, variation in the in-plane etching rate distribution can in turn be reduced.

According to the exemplary embodiment of the present disclosure, even when a change occurs in the distribution of the ion flux that occurs between the plasma generated in the plasma processing and the substrate, the temporal change in the ion flux distribution can be readily corrected by correcting a parameter of the plasma processing. The change in the ion flux distribution may be caused, for example, by wear of any of the parts of the plasma processing apparatus 1 over time. The part may include the ring assembly, such as a focus ring.

According to the exemplary embodiment of the present disclosure, the ion flux distribution may be corrected on a substrate basis as an example. Inter-substrate variation in the plasma processing can thus be suppressed.

The embodiment of the present disclosure further includes the aspects below.

### (Appendix 1)

A plasma processing method for performing plasma processing in a plasma processing apparatus including a chamber and a substrate support disposed in the chamber, the plasma processing performed on a substrate placed at the substrate support by generating plasma in the chamber, the method including:
(a) the step of storing in advance first distribution data that is data relating to a distribution of an ion flux that occurs between the plasma generated in the chamber and a first substrate placed at the substrate support;
(b-a) the step of placing a second substrate at the substrate support; and
(b-b) a plasma processing step of generating the plasma in the chamber based on the first distribution data to perform the plasma processing on the second substrate.

### (Appendix 2)

The plasma processing method according to Appendix 1, wherein
the storing step (a) includes the steps of
(a-a) placing the first substrate at the substrate support,
(a-b) generating the plasma in the chamber to perform the plasma processing on the first substrate,
(a-c) supplying power to each of multiple heaters disposed in the substrate support,
(a-d) acquiring the power supplied to each of the multiple heaters in the state in which the plasma is generated in the chamber, and
(a-e) calculating the first distribution data based on the power acquired for each of the multiple heaters in the first power acquisition step.

### (Appendix 3)

The plasma processing method according to Appendix 1 or 2, further including the steps of:
(c-a) placing a reference substrate at the substrate support;
(c-b) generating the plasma in the chamber to perform the plasma processing on the reference substrate;
(c-c) supplying power to each of multiple heaters disposed in the substrate support;
(c-d) acquiring the power supplied to each of the multiple heaters in the state in which the plasma is generated in the chamber; and
(c-e) calculating reference distribution data that is data indicating a distribution of an ion flux that occurs between the reference substrate and the plasma, the reference distribution data being calculated based on the power acquired for each of the multiple heaters in the reference power acquisition step,
wherein in the plasma processing step (b-b), the plasma is generated based on the reference distribution data and the first distribution data.

### (Appendix 4)

The plasma processing method according to any one of Appendices 1 to 3, wherein the plasma processing step (b-b) includes generating the plasma in the chamber based on a difference between the reference distribution data and the first distribution data.

### (Appendix 5)

The plasma processing method according to any one of Appendices 1 to 4, wherein
the plasma processing apparatus further includes a storage configured to store a table that associates (1) an amount of change in a distribution of an electron density of the plasma generated in the chamber with (2) an amount of change in a distribution of an ion flux that occurs between the substrate placed at the substrate support and the plasma generated in the chamber, and
the plasma processing step (b-b) includes the step of controlling the distribution of the electron density based on a difference between the reference distribution data and the first distribution data by referring to the table stored in the storage.

### (Appendix 6)

The plasma processing method according to Appendix 5, wherein
the plasma processing apparatus further includes multiple electromagnets disposed so as to face the substrate support, and
the step of controlling the distribution of the electron density includes the step of controlling at least one of a current and a voltage supplied to the multiple electromagnets to control the distribution of the electron density.

### (Appendix 7)

The plasma processing method according to Appendix 2, wherein
the substrate support has a substrate supporting surface configured to support the substrate,
the substrate support surface has multiple support regions, and
the multiple heaters are disposed in the substrate support in the respective multiple support regions.

### (Appendix 8)

The plasma processing method according to Appendix 3, wherein the reference substrate, the first substrate, and the second substrate each include a mask film having the same opening pattern.

### (Appendix 9)

The plasma processing method according to Appendix 5 or 6, further including the step of
generating the table, wherein the step of generating the table includes the steps of placing a dummy substrate at the substrate support,
controlling the power supplied to each of the multiple heaters in such a way that a temperature of each of the multiple heaters becomes a predetermined temperature with the dummy substrate placed at the substrate support,
placing the dummy substrate at the substrate support,
generating the plasma in the chamber to perform the plasma processing on the dummy substrate,
changing the distribution of the electron density of the plasma in a state in which the plasma processing is performed on the substrate including the mask film to acquire the power supplied to each of the multiple heaters, and
storing (1) the amount of change in the distribution of the electron density of the plasma generated in the chamber and (2) the amount of change in the distribution of the ion flux that occurs between the substrate placed at the substrate support and the plasma generated in the chamber in the table in association with each other.

### (Appendix 10)

The plasma processing method according to any one of Appendices 1 to 4, wherein
the plasma processing apparatus further includes a storage configured to store a table that associates (1) an amount of change in a distribution of a bias voltage that occurs between the substrate placed at the substrate support and the plasma generated in the chamber with (2) an amount of change in a distribution of an ion flux that occurs between the substrate placed at the substrate support and the plasma generated in the chamber, and
the plasma processing step (b-b) includes the step of controlling the distribution of the bias voltage based on a difference between the reference distribution data and the first distribution data by referring to the table stored in the storage.

### (Appendix 11)

The plasma processing method according to Appendix 10, wherein
the plasma processing apparatus further includes a ring assembly disposed around the substrate support, and
the step of controlling the distribution of the bias voltage includes controlling a voltage applied to the ring assembly to control the distribution of the bias voltage.

### (Appendix 12)

The plasma processing method according to Appendix 10, wherein
the plasma processing apparatus further includes
a ring assembly disposed around the substrate support, and
an actuator configured to adjust a height of the ring assembly relative to a height of the substrate support, and
the step of controlling the distribution of the bias voltage includes adjusting the height of the ring assembly to control the distribution of the bias voltage.

### (Appendix 13)

A plasma processing apparatus including: a chamber, a substrate support disposed in the chamber, and a controller, wherein the controller is configured to
(a) store in advance reference distribution data that is data relating to a distribution of an ion flux that occurs between plasma generated in the chamber and a first substrate placed at the substrate support,
(b-a) place a second substrate at the substrate support, and
(b-b) generate the plasma in the chamber based on the reference distribution data to perform plasma processing on the second substrate.

The aforementioned embodiment has been described for illustration, and is not intended to limit the scope of the present disclosure. Various modifications may be made to the embodiment described above without departing from the scope and gist of the present disclosure. For example, some components in the embodiment may be added to another embodiment. Some components in the embodiment may be replaced with corresponding components in another embodiment.

1. A plasma processing method comprising:
(a) the step of storing, in memory, first distribution data relating to a distribution of an ion flux that occurs between plasma generated in a chamber and a first substrate placed at a substrate support disposed in the chamber;
(b-a) the step of placing a second substrate on the substrate support; and
(b-b) a plasma processing step of generating plasma in the chamber based on the first distribution data to perform the plasma processing on the second substrate.

2. The plasma processing method according to claim 1, wherein
the storing step (a) includes the steps of
(a-a) placing the first substrate on the substrate support,
(a-b) generating the plasma in the chamber to perform the plasma processing on the first substrate,
(a-c) supplying power to each of multiple heaters disposed in the substrate support,
(a-d) acquiring the power supplied to each of the multiple heaters in the state in which the plasma is generated in the chamber, and
(a-e) calculating the first distribution data based on the power acquired for each of the multiple heaters in the first power acquisition step.

3. The plasma processing method according to claim 1, further comprising the steps of:
(c-a) placing a reference substrate at the substrate support;
(c-b) generating the plasma in the chamber to perform the plasma processing on the reference substrate;
(c-c) supplying power to each of multiple heaters disposed in the substrate support;
(c-d) acquiring the power supplied to each of the multiple heaters in the state in which the plasma is generated in the chamber; and
(c-e) calculating reference distribution data indicating a distribution of an ion flux that occurs between the reference substrate and the plasma, the reference distribution data being calculated based on the power acquired for each of the multiple heaters in the reference power acquisition step,
wherein in the plasma processing step (b-b), the plasma is generated based on the reference distribution data and the first distribution data.

4. The plasma processing method according to claim 3, wherein the plasma processing step (b-b) includes generating the plasma in the chamber based on a difference between the reference distribution data and the first distribution data.

5. The plasma processing method according to claim 4, further comprising
storing, by the memory, a table that associates (1) an amount of change in a distribution of an electron density of the plasma generated in the chamber with (2) an amount of change in a distribution of an ion flux that occurs between the substrate placed at the substrate support and the plasma generated in the chamber, and
the plasma processing step (b-b) includes the step of controlling the distribution of the electron density based on a difference between the reference distribution data and the first distribution data by referring to the table stored in the memory.

6. The plasma processing method according to claim 5, wherein
the plasma processing apparatus further includes multiple electromagnets disposed so as to face the substrate support, and
the step of controlling the distribution of the electron density includes the step of controlling at least one of a current and a voltage supplied to the multiple electromagnets to control the distribution of the electron density.

7. The plasma processing method according to claim 2, wherein
the substrate support has a substrate supporting surface configured to support the substrate,
the substrate supporting surface has multiple support regions, and
the multiple heaters are disposed in the respective multiple support regions.

8. The plasma processing method according to claim 3, wherein the reference substrate, the first substrate, and the second substrate each include a mask film having the same opening pattern.

9. The plasma processing method according to claim 5, further comprising the step of
generating the table, wherein the step of generating the table includes the steps of placing a dummy substrate at the substrate support,
controlling the power supplied to each of the multiple heaters to maintain each of the multiple heaters at a predetermined temperature with the dummy substrate placed at the substrate support,
placing the dummy substrate at the substrate support,
generating the plasma in the chamber to perform the plasma processing on the dummy substrate,
changing the distribution of the electron density of the plasma in a state in which the plasma processing is performed on the substrate to acquire the power supplied to each of the multiple heaters, and
storing in the memory (1) the amount of change in the distribution of the electron density of the plasma generated in the chamber and (2) the amount of change in the distribution of the ion flux that occurs between the substrate placed at the substrate support and the plasma generated in the chamber, in the table in association with each other.

10. The plasma processing method according to claim 4, further comprising
storing, by the memory, a table that associates (1) an amount of change in a distribution of a bias voltage that occurs between the substrate placed at the substrate support and the plasma generated in the chamber with (2) an amount of change in a distribution of an ion flux that occurs between the substrate placed at the substrate support and the plasma generated in the chamber, and
the plasma processing step (b-b) includes the step of controlling the distribution of the bias voltage based on a difference between the reference distribution data and the first distribution data by referring to the table stored in the memory.

11. The plasma processing method according to claim 10, wherein
the plasma processing apparatus further includes a ring assembly disposed around the substrate support, and
the step of controlling the distribution of the bias voltage includes controlling a voltage applied to the ring assembly to control the distribution of the bias voltage.

12. The plasma processing method according to claim 10, wherein
the plasma processing apparatus further includes:
a ring assembly disposed around the substrate support, and
an actuator configured to adjust a height of the ring assembly relative to a height of the substrate support, and
the step of controlling the distribution of the bias voltage includes adjusting the height of the ring assembly to control the distribution of the bias voltage.

13. A plasma processing apparatus comprising:
a chamber;
a substrate support disposed in the chamber;
memory; and a controller,
wherein the controller is configured to
(a) store, in the memory, first distribution data that is data relating to a distribution of an ion flux that occurs between plasma generated in the chamber and a first substrate placed at the substrate support,
(b-a) place a second substrate at the substrate support, and
(b-b) generate the plasma in the chamber based on the first distribution data to perform plasma processing on the second substrate.

14. The plasma processing apparatus according to claim 13, wherein
the storing step (a) includes the steps of
(a-a) placing the first substrate on the substrate support,
(a-b) generating the plasma in the chamber to perform the plasma processing on the first substrate,
(a-c) supplying power to each of multiple heaters disposed in the substrate support,
(a-d) acquiring the power supplied to each of the multiple heaters in the state in which the plasma is generated in the chamber, and
(a-e) calculating the first distribution data based on the power acquired for each of the multiple heaters in the first power acquisition step.

15. The plasma processing apparatus according to claim 13, wherein the controller is further configured to:
(c-a) place a reference substrate at the substrate support;
(c-b) generate the plasma in the chamber to perform the plasma processing on the reference substrate;
(c-c) supply power to each of multiple heaters disposed in the substrate support;
(c-d) acquire the power supplied to each of the multiple heaters in the state in which the plasma is generated in the chamber; and
(c-e) calculate reference distribution data indicating a distribution of an ion flux that occurs between the reference substrate and the plasma, the reference distribution data being calculated based on the power acquired for each of the multiple heaters in the reference power acquisition step,
wherein in the plasma processing step (b-b), the plasma is generated based on the reference distribution data and the first distribution data.

16. The plasma processing apparatus according to claim 15, wherein the plasma processing step (b-b) includes generating the plasma in the chamber based on a difference between the reference distribution data and the first distribution data.

17. The plasma processing apparatus according to claim 16, wherein
the memory is configured to store a table that associates (1) an amount of change in a distribution of an electron density of the plasma generated in the chamber with (2) an amount of change in a distribution of an ion flux that occurs between the substrate placed at the substrate support and the plasma generated in the chamber, and
the plasma processing step (b-b) includes the step of controlling the distribution of the electron density based on a difference between the reference distribution data and the first distribution data by referring to the table stored in the memory.

18. The plasma processing apparatus according to claim 17, wherein
the plasma processing apparatus further includes multiple electromagnets disposed so as to face the substrate support, and
the step of controlling the distribution of the electron density includes the step of controlling at least one of a current and a voltage supplied to the multiple electromagnets to control the distribution of the electron density.

19. The plasma processing apparatus according to claim 14, wherein
the substrate support has a substrate supporting surface configured to support the substrate,
the substrate supporting surface has multiple support regions, and
the multiple heaters are disposed in the respective multiple support regions.

20. The plasma processing apparatus according to claim 15, wherein the reference substrate, the first substrate, and the second substrate each include a mask film having the same opening pattern.
